(19) United States
(12) Patent Application Publication
(10) Pub. No.: US 2017/0345616 A1
(43) Pub. Date: Nov. 30, 2017

(54) SYSTEMS AND METHODS FOR ADAPTIVE SCANNING

(71) Applicant: EDAX, Incorporated, Mahwah, NJ (US)

(72) Inventor: Julio C. Liriano, Fort Lee, NJ (US)

(21) Appl. No.: 15/606,784

(22) Filed: May 26, 2017

Related U.S. Application Data
(60) Provisional application No. 62/343,649, filed on May 31, 2016.

(51) Int. Cl. H01J 37/28; G01T 1/169; G06F 17/18; H01J 37/244

(52) U.S. Cl. CPC H01J 37/28; H01J 37/244; G01T 1/169; G06F 17/18

(57) ABSTRACT

A system for collection information from a sample includes a scan generator having a first communication channel and a second communication channel. The first communication channel provides data communication between the scan generator and one or more sampling location movement devices. The second communication channel provides data communication with one or more signal detectors.

### CROSS-REFERENCE TO RELATED APPLICATIONS

This application claims priority to and the benefit of U.S. Provisional Application No. 62/343,649, filed May 31, 2016, the entirety of which is herein incorporated by reference.

### BACKGROUND OF THE DISCLOSURE

Data collection systems are used for material analysis and microanalysis of a variety of material properties including chemical, structural, mechanical, crystallographic, or other information. For example, Energy Dispersive Spectrometry (“EDS”) has grown into a robust analytic technique for the measurement of material properties. EDS is an analytical technique performed in a scanning electron microscope (“SEM”) or transmission electron microscope (“TEM”) in a low pressure or near vacuum environment. A sample is positioned beneath a column housing an electron source. The electron source may be any suitable source, such as a tungsten filament, thermal field emission, or LaB6 electron source. The electron source may emit electrons that are directed in a beam through the column and toward a sample chamber. The sample chamber may be connected to the column and allow a sample to be held in line with the electron beam for imaging and/or sampling. The sample may have an unprepared surface allowing sampling of the exposed surface (such as particles or broken and/or cut surfaces) or a prepared surface that is substantially flat. Non-conductive samples may be made more conductive by deposition of a conductive layer over at least part of the surface in order to provide a conductive path to ground. For example, carbon layers or gold layers sputtered onto the surface of a sample can provide a conductive layer that dissipates charge from the sample to the sample stage or other ground within the sample chamber.

Referring now to FIG. 1, conventional EDS may be conducted in a data collection system 100 by presenting a sample 102 at in line with an electron beam 104. The surface of the sample 102 may be oriented perpendicularly to the electron beam 104 or may be oriented at an angle not perpendicular to the electron beam 104. For a sample 102 with an uneven surface, tilting of the sample provides line-of-sight to features that are otherwise inaccessible by the electron beam 104. The position of the sample 102 relative to the beam 104 may be achieved by tilted a sample stage 106 or by providing a sample holder (not shown) having non-parallel surfaces mounted to the sample stage 106 or a combination of the two.

Lenses, such as electromagnetic lenses, may focus and/or deflect the electron beam 104 at different working distances (focal length beneath a lowest point of the column) and/or locations on the sample 102. A “scan” of the data collection system 100 may include construction of an image of a surface of the sample 102 by rastering the beam 104 through a predetermined range of positions and/or deflections of the beam 104. A combination of an EDS detector 110 and rastering of the beam 104 allow for the construction of X-ray count maps of a portion of the sample 102.

The interaction of the electron beam 104 and the sample 102 causes the atoms of the sample 102 to become excited. When an electron or electrons of an atom relaxes to a lower-energy ground state, the atom will emit energy in the form of an X-ray. The X-ray will have a particular energy that correlates to the state of the electron that emitted the X-ray. For example, electrons in the K energy level of the atom will emit an X-ray with a different energy than electrons in the L energy level. The X-rays will also vary in energy depending on the element emitting the X-ray. For example, electrons of the K energy level in aluminum will emit X-rays of different energy than the electrons of the K energy level in iron. Measurement of the X-ray energy allows for differentiation of elements excited by the electron beam 104. The relative quantity of X-ray counts in a given period of time indicates relative concentration of those elements in the sample 102 excited by the electron beam 104.

The EDS detector 110 includes a detection surface that converts X-rays into a voltage signal. The voltage signal is the provided to a pulse processor that measures the signal and passes them to an analyzer, which will then display the data and allow further analysis by a user. The detection surface can be a semiconductor that is cooled to low temperatures, for example, by liquid nitrogen or by Peltier cooling. EDS detectors include silicon-lithium (“Si(Li)”) detectors and newer silicon drift detectors (“SDDs”).

Rastering the electron beam 104 across the surface of a sample 102 allows for the collection of X-ray count maps of the surface. The X-ray maps can include individually selected energy channels or each data point within the map can include a full spectrum for the point. Calculating the relative concentrations of various elements in the sample 102 is performed by comparing the relative intensities of energy channels having local maximum in the X-ray spectrum of each point.

During X-ray mapping of a sample 102, the individual sampling locations of the surface have relatively low quantities of X-ray counts detected by the EDS detector 110. The relatively low X-ray counts result in low-resolution spectra and/or poor statistical quality of the elemental identification. The EDS detector 110 is limited by the physical collection area of the detection surface in the EDS detector 110 and by the energy resolution that the EDS detector 110 can maintain as throughput increases. Recent advancements in EDS detectors 110 have allowed increased collection rates of X-ray counts and data collection system 100 improvements have allowed for greater current to be applied to the sample 102 by the electron beam 104. The increased collection rates of X-ray counts create a greater discrepancy in the statistics when the electron beam 104 falls onto a portion of the sample 102 generating lower count rates. The count rate for a particular sampling location is affected by the sample composition (i.e., atomic weight of the elements present), sample geometry, and beam conditions.

In conventional EDS mapping and other data collection techniques for material analysis, the dwell time per sampling location is set at the beginning of the mapping collection run, and the dwell time is constant for the duration of the mapping. The dwell time is set based on user-selected sampling locations during setup of the mapping; the dwell time is a user-specified estimate of the time needed to attain satisfactory statistics at each sampling location. While data collection rates have increased in recent years, improvements to statistics, particularly early in the scan of a sample 102, are desirable.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In an embodiment, a system for collecting information from a sample includes a scan generator having a first communication channel and a second communication channel. one or more sampling location movement devices. The first communication channel provides data communication between the scan generator and one or more sampling location movement devices. The second communication channel provides data communication with one or more signal detectors.

In another embodiment, a method for collecting information from a sample includes directing an energy source at a first sample location and generating a location signal with an interaction of the energy source and the first sample location. The method further includes detecting the location signal with a signal detector, aggregating the location signal into a total location signal, and comparing the total location signal to a termination threshold. If at least part of the total location sign meets or exceeds the termination threshold, sending a stop command to the signal detector.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims, or may be learned by the practice of such embodiments as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a partial cutaway side view of an embodiment of a system for collecting data from a sample, according to the present disclosure;

FIG. 2 is a flowchart depicting an embodiment of a method of collecting data from a sample, according to the present disclosure;

FIG. 3 is a schematic representation of an embodiment of a system for collecting data from a sample, according to the present disclosure;

FIG. 4 is a partial cutaway side view of a system generating a location signal, according to the present disclosure;

FIG. 5 is an embodiment of an aggregated location signal; according to the present disclosure;

FIG. 6. is a partial cutaway side view of the system of FIG. 4, according to the present disclosure; and

FIG. 7 is a detail view of the sampling locations of FIG. 6, according to the present disclosure.

### DETAILED DESCRIPTION

One or more specific embodiments of the present disclosure will be described below. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

This disclosure generally relates to data collection devices, systems, and methods for collecting information from a sample. More specifically, the present disclosure relates to improved communications between an X-ray, electron, or other signal detector and an energy source and/or beam.

While the present disclosure may describe one or more embodiments of a detector in relation to an electron beam, it should be understood that the present disclosure may be applicable to material analysis, imaging, testing, or combinations thereof including an X-ray source, microwave source, ion source, proton source, gamma source, visible light source, laser source, or any other directed energy source. In some embodiments, the energy source may be a focused beam energy source, such as one providing a focused electron beam, X-ray beam, ion beam, etc. In other embodiments, the energy source may be a broad beam energy source, such as one providing a broad X-ray beam, microwave beam, ion source, etc. For example, a focused beam may be a beam that may have an incident diameter at a sample surface of 5 microns or less.

While the present disclosure may describe one or more embodiments of scan generator coils as a sampling location movement device, it should be understood that any suitable mechanism configured to move the energy beam and the sample relative to one another may be used as a sampling location movement device. In some embodiments, the sampling location movement device may deflect and/or redirect the energy beam and/or energy source relative to a stationary sample. In other embodiments, the sampling location movement device may move the sample relative to the energy beam and/or energy source.

In an example, a scan generator (“SG”) provides communication between the scan coils of an SEM and an EDS detector. The scan coils may deflect an electron beam from the SEM and direct the electron beam at a sampling location on a sample. The electron beam may excite atoms at or near the sampling location, which may generate a location signal. The scan coils may remain at a constant voltage, and, after a settling time, the SG may pass a “collect” command to the EDS detector. The EDS detector may then collect X-ray counts of the location signal. Conventionally, after a dwell time, the SG may pass a “stop” command to the EDS detector, and the EDS detector may stop collecting X-ray counts. The SG may send a “move” command to the scan coils to move the electron beam a predetermined speed, distance, direction, or combination thereof. In conventional EDS mapping, the dwell time is provided by a user and remains constant for the duration of the EDS mapping session.

An SG according to the present disclosure may provide for two-way communication with the SEM and/or a signal detector. In some embodiments, the SG may pass a “collect” command to the signal detector. The signal detector may then collect the signal, such as X-ray counts, of the location signal. The signal detector may collect at least part of the location signal and aggregate the location signal during collection. For example, a Digital Pulse Processor (“DPP”) of an EDS detector may aggregate the X-ray counts until a total location signal equals or exceeds a signal threshold, such as total X-ray counts, a signal-to-background ratio, region of interest X-ray counts, other signal or combinations thereof.

After the total location signal equals or exceeds a signal threshold, the signal detector may pass a “complete” command SG, and the signal detector stops collecting location signal. The SG may acknowledge the “complete” command with an acknowledgement communication to the signal detector and send a “move” command to the scan coils to move the electron beam a predetermined speed, distance, direction, or combination thereof. The acknowledgement communication may reset the signal detector such that the signal detector is readied to receive a new “collect” command from the SG. The two-way communication between the SG and a detector may allow for more efficient and/or normalized signal collection from sampling locations.

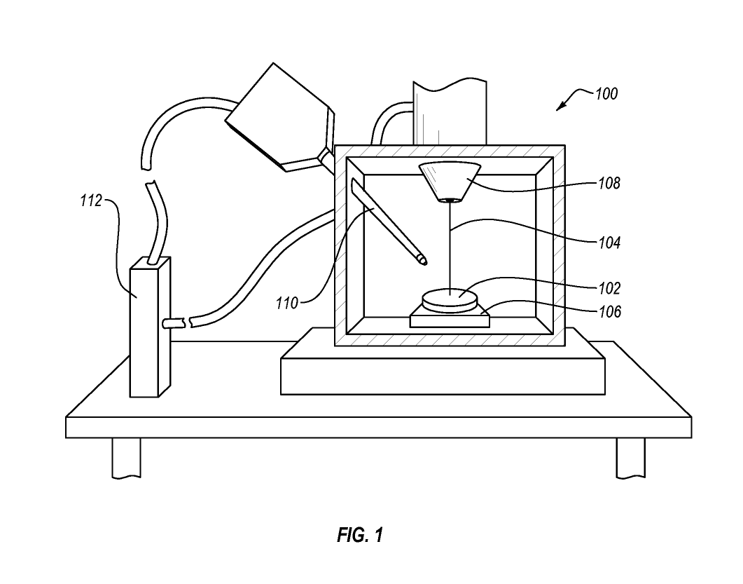

FIG. 1 illustrates a data collection system 100 having a sample 102 located in line with a beam 104. While the present example of a data collection system 100 is an SEM and an electron beam, the present disclosure may be applicable to other analysis techniques, such as those utilizing focused and/or broad energy beams from an energy beam source such as an X-ray source, microwave source, ion source, proton source, gamma source, visible light source, laser source, any other directed energy source, or combinations thereof. The sample 102 may be located on a sample stage 106. A sampling location movement device 108 may include the sample stage 106 and/or beam 104 optics of the data collection system 100. In some embodiments, the sample stage 106 may be movable relative to the beam 104 to alter the location of the beam 104 relative to the sample 102. In other embodiments, optics in a column of the data collection system 100, such as scan coils, may move (i.e., deflect) the beam 104 relative to the sample stage 106 to alter the location of the beam 104 relative to the sample 102. In other embodiments, both the sample stage 106 may be movable relative to the beam 104 and the beam 104 may move (i.e., deflect) relative to the sample stage 106.

A signal detector 110 may collect a signal generated by the interaction of the beam 104 and the sample 102. In some embodiments, the signal detector may be an X-ray detector (such as an energy dispersive spectrometer, wavelength dispersive spectrometer, or other X-ray detectors), an electron detector (such as a backscatter electron detector, a secondary electron detector, an electron backscatter diffraction (“EBSD”) detector, a forescatter electron detector, or other electron detectors), a photon detector (such as a charge coupled device or other photon detector), a microwave detector, an ion detector, a proton detector, a cadmium telluride EDS detector, or other signal detectors used in the art.

The signal detector 110 may be in data communication with an SG 112. In some embodiments, the SG 112 may be a standalone or external SG 112. In other embodiments, the SG 112 may be integrated with one or more components of the data collection system 100. For example, the SG 112 may be in data communication with the sampling location movement device 108 to at least partially control and/or provide commands to direct the movement of the beam 104 and sample 102 relative to one another.

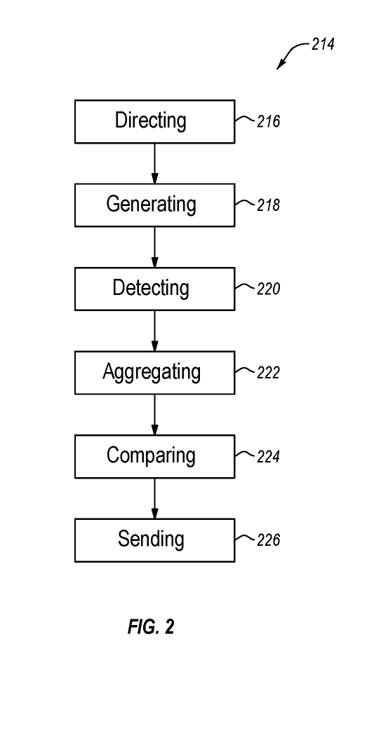

FIG. 2 illustrates an embodiment of a method 214 of collecting information from a sample. The method 214 may include directing 216 an energy source at a first sample location and generating 218 a location signal with an interaction of the energy source and the sample location. As described herein, the energy source may be any suitable energy source. Directing 216 the energy source may include directing a beam at the first sample location. In some embodiments, the beam may be a focused beam with a diameter no greater than 5 microns at the first sample location. In other embodiments, the beam may be a broad beam with a diameter greater than 5 microns at the first sample location.

In some embodiments, generating 218 a location signal may be at least partially dependent upon the energy source. For example, generating 218 a backscatter electron signal may include directing 216 an electron beam at the first sample location. In other examples, generating 218 a secondary X-ray signal may include directing 216 an electron beam and/or an X-ray beam at the first sample location. In some embodiments, generating 218 a location signal may include generating a location signal emitted from the first sample location upon energizing and/or exciting the sample at the first sample location. For example, the location signal may include secondary electrons and/or secondary X-rays emitted from the sample upon relaxation of an atom from an excited state. In other embodiments, generating 218 a location signal may include a signal including waves and/or particles from the beam diffracted and/or scattered from the first sample location. For example, the signal may include at least some of the incident electrons of an electron beam backscattered toward a backscatter detector.

The method 218 may further include detecting 220 the location signal with a detector and aggregating 222 the location signal into a total location signal. The total location signal may be the location signal aggregated over a duration of time. The duration of time may be at least partially dependent on the location signal amplitude and collection efficiency of the detector. For example, an X-ray signal at the first sample location may be aggregated for a longer duration of time to aggregate the same amount of location signal when the amount of secondary X-rays emitted by the excited sample is lower. The location signal may be lower when a lower incident energy and/or amplitude is provided by the beam. In some embodiments, the duration of time of aggregating 222 the location signal may be initially indefinite. For example, the predetermined dwell time at the location may be undefined and/or infinite. In other embodiments, a time out duration may be provided to prevent indefinite dwell period. For example, aggregating 222 the location signal may be set to time out after 10 seconds of detecting 220 the location signal at the first sample location. In other examples, aggregating 222 the location signal may be set to time out after 10 seconds of directing 216 an energy source at a first sample location.

The method 214 may further include comparing 224 the total location signal to a termination threshold and sending 226 a “complete” command to the SG when the total location signal matches or exceeds the termination threshold. In some embodiments, the termination threshold may be a user-defined value. For example, the termination threshold may be a nominal value of a quantity of X-ray counts. In other examples, the termination threshold may be a nominal value of a quantity counts within a region of interest (“ROI”) in an X-ray spectrum. In other embodiments, the termination threshold may be a calculated value. For example, the termination threshold may be a signal to background ratio, such as 4:1, 6:1, 8:1, 10:1, 20:1, greater than 20:1, or any values therebetween. In other examples, the termination threshold may be a contrast ratio in a backscatter electron image.

In some embodiments, sending 226 a “complete” command may include sending a stop command from one or more of a plurality of detectors. For example, the method 214 may include detecting 220 and aggregating 222 a location signal with a first detector and sending 226 a “complete” command from the first detector and/or a second detector to the SG and terminating aggregation of the location signal with both the first detector and the second detector. The first detector and second detector may detect the same or different portions of the location signal. For example, the first detector may be an X-ray detector and the second detector may be an electron detector. In at least one example, the first detector may be an EDS detector that detects secondary electrons emitted by excited atoms at the sampling location and the second detector may be an EBSD detector that detects electrons diffracted from the sampling location.

In some embodiments, the “complete” command may be sent when a first total location signal detected and aggregated by the first detector equals or exceeds a termination threshold. In other embodiments, the “complete” command may be sent when a second total location signal detected and aggregated by the second detector equals or exceeds a termination threshold. The “complete” command may, therefore, stop the collection of the first location signal and second location signal when either the first total location signal or the second total location signal equals or exceeds a termination threshold.

Sending 226 a “complete” command may additionally include sending a “move” command to the sample location movement device (e.g., optics and/or stage controls to move the beam and/or sample relative to one another) to direct the beam at a second sample location. For example, the method 214 may include sending 226 the “complete” command to the SG and stopping aggregating the first location signal and sending 226 a “move” command to move the beam to the second sample location when the total location signal equals or exceeds the termination threshold. In this way, the effective dwell time of detecting 220 and aggregating 222 the location signal at the first sample location (and each sample location) is normalized to the termination threshold value.

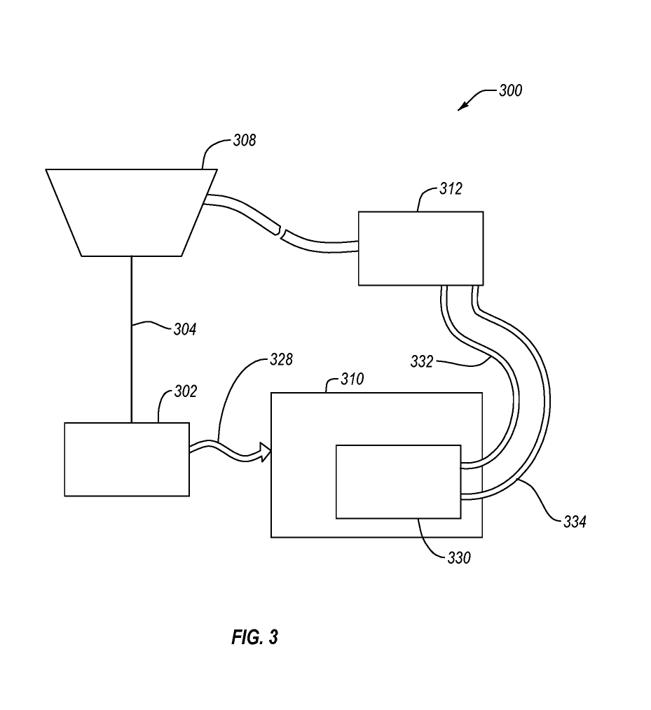

FIG. 3 through FIG. 7 illustrate one or more embodiments of a method of collecting information from a sample, according to the present disclosure. FIG. 3 is a schematic illustration of the communication between various components of a data collection system 300 configured to perform an embodiment of the method described herein. In some embodiments, the data collection system 300 may include an electron microscope like that described in relation to FIG. 1. In other embodiments, the data collection system 300 may include one or more other energy sources, as described herein.

The data collection system 300 may include an energy beam 304 directed at a sample 302. The interaction of the energy beam 304 and a sampling location of the sample 302 may generate one or more location signals 328. The one or more location signals 328 may be detected by a signal detector 310. The detector 310 may be a variety of detectors, as described herein. In at least one embodiment, the detector 310 may be an X-ray detector. The X-ray detector may include a pulse processor 330.

The pulse processor 330 and/or detector 310 may be configured to have two-way data communication with the SG 312. In some embodiments, the pulse processor 330 and/or detector 310 may be in data communication with an SG 312 by a first communication cable 332 and a second communication cable 334. The first communication cable 332 may allow data communication from the detector 310 and/or pulse processor 330 to the SG 312 and the second communication cable 334 may allow data communication to the detector 310 and/or pulse processor 330 from the SG 312. In other embodiments, the pulse processor 330 and/or detector 310 may be in data communication with an SG 305 by a first communication cable 332 that allows two-way data communication between the detector 310 and/or pulse processor 330 and the SG 312.

The SG 312 may be communication with a sampling location movement device 308, such as optics or other device for directing and/or deflecting the energy beam 304 relative to the sample 302, and/or sample stage controls for moving the sample 302 relative to the energy beam 304.

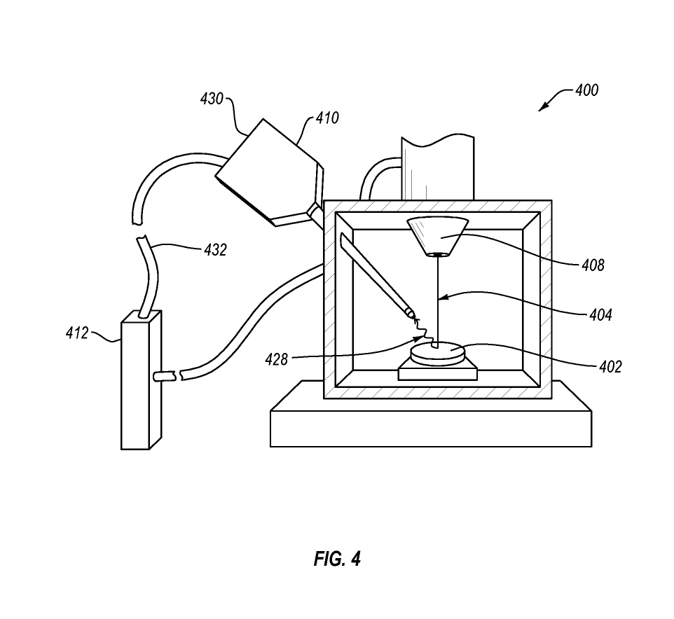

FIG. 4 illustrates an embodiment of a data collection system 400 during the generation of one or more location signals 428 from a sample 402. A signal detector 410 may detect the location signal 428. The signal detector 410 may be in data communication with an SG 412. The signal detector 410 may receive a “collect” command from the SG 412 through a communication cable 432 to begin collection. In some embodiments, the signal detector 410 may have a pulse processor 430 that may be in data communication with the SG 412 and may communicate information about the location signal 428 signal to the SG 412. In other embodiments, the pulse processor 430 may be integrated with the SG 412.

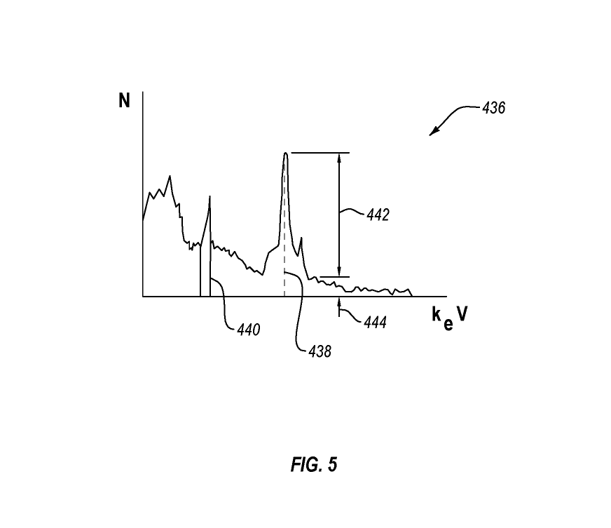

FIG. 5 illustrates an embodiment of the information collected by the signal detector 410 and/or pulse processor 430. In some embodiments, the information may be spectral information, such as information from an X-ray spectrum of secondary electrons. While an embodiment of an X-ray spectrum 436 is illustrated in FIG. 5, in other embodiments, the information sent from the detector may be other types of information from the sample, such as backscatter electron information, secondary electron information, crystallographic information, chemical information, structural information, electronic property information, other types of material information, or combinations thereof.

Various embodiments of types of termination thresholds are illustrated in FIG. 5 in relation to an X-ray spectrum 436. In some embodiments, the termination threshold may be an energy channel 438 threshold. For example, the termination threshold may be an aggregated predetermined quantity (N) of detected X-ray counts at a selected energy channel 438. Upon equaling or exceeding the predetermined quantity of detected X-ray counts in the selected energy channel 438, the termination threshold is met and a “complete” command may be sent to the SG. In other embodiments, the termination threshold may be a region of interest (“ROI”) 440 threshold. For example, the termination threshold may be an aggregated predetermined quantity (N) of detected X-ray counts within a selected ROI 440, such as all detected X-ray counts between 1.8 keV and 2.0 keV. Upon equaling or exceeding the predetermined quantity of detected X-ray counts in the selected ROI 440, the termination threshold is met and a “complete” command may be sent.

In yet other embodiments, the termination threshold may be a peak height 442 threshold. For example, the termination threshold may be an aggregated predetermined quantity (N) of detected X-ray counts at a selected energy channel 438 above the background 444. In other words, the termination threshold may be an aggregated predetermined quantity of detected X-ray counts in a selected energy channel 438 minus the number of x-ray counts determined to be background 444 events that are not attributable to signal the sample. This may allow the system (such as system 400 of FIG. 4) to distinguish the signal from the noise of the sample. Upon equaling or exceeding the predetermined quantity of detected X-ray counts in the selected energy channel 438 above the background 444, the termination threshold is met and a “complete” command may be sent.

In further embodiments, the termination threshold may be a ratio of peak height 442 to background 444. The peak height 442 to background 444 for a given energy channel 438 may be the signal-to-noise ratio of the location signal for that energy channel 438. Upon equaling or exceeding the desired signal-to-noise ratio of peak height 442 to background 444 for a given energy channel 438, the termination threshold is met and a “complete” command may be sent. In some embodiments, the signal-to-noise ratio may be in a range having upper and lower values including any of 0.1, 0.2, 0.3, 0.4, 0.5, 0.6, 0.7, 0.8, 0.9, 1.0, 1.5, 2.0, 3.0, 4.0, 5.0, 10.0, 20.0, or any values therebetween. For example, the termination threshold may be a signal-to-noise ratio in a range of 0.1 to 20.0. In other examples, the termination threshold may be a signal-to-noise ratio in a range of 0.5 to 10.0. In yet other examples, the termination threshold may be a signal-to-noise ratio in a range of 1.0 to 5.0.

In some embodiments, a first termination threshold may be used in addition to a second termination threshold. For example, a first termination threshold may be a signal-to-noise ratio and a second termination threshold may be a peak height. Requiring both termination threshold to be met before sending a “complete” command may aid in preventing premature termination. In some examples, a signal-to-noise ratio of greater than 1.0 may be prematurely met by two X-ray counts (one calculated to be background, and one calculated to be signal) without collecting a statistically significant quantity of X-ray counts overall. Hence, the second termination threshold may be a peak height 442 of 5,000 detected X-ray counts in the energy channel 438. When at least 5,000 X-ray counts are aggregated in the signal of the energy channel 438 and the peak height 442 is greater than the background 444 in the energy channel 438, the termination thresholds may be met and the “complete” command may be sent.

In other embodiments, a first termination threshold may be used in alternative to a second termination threshold. For example, a first termination threshold may be a peak height 442 in a selected energy channel 438 and a second termination threshold may be an aggregated quantity of X-ray counts in an ROI 440. The energy channel 438 may be an energy channel outside the ROI 440, as shown in FIG. 5. For example, in a multiphase sample, the ROI 440 may include X-ray counts representative of a first phase, while the energy channel 438 may be representative of a second phase. In other embodiments, the energy channel 438 may be an energy channel within the ROI 440.

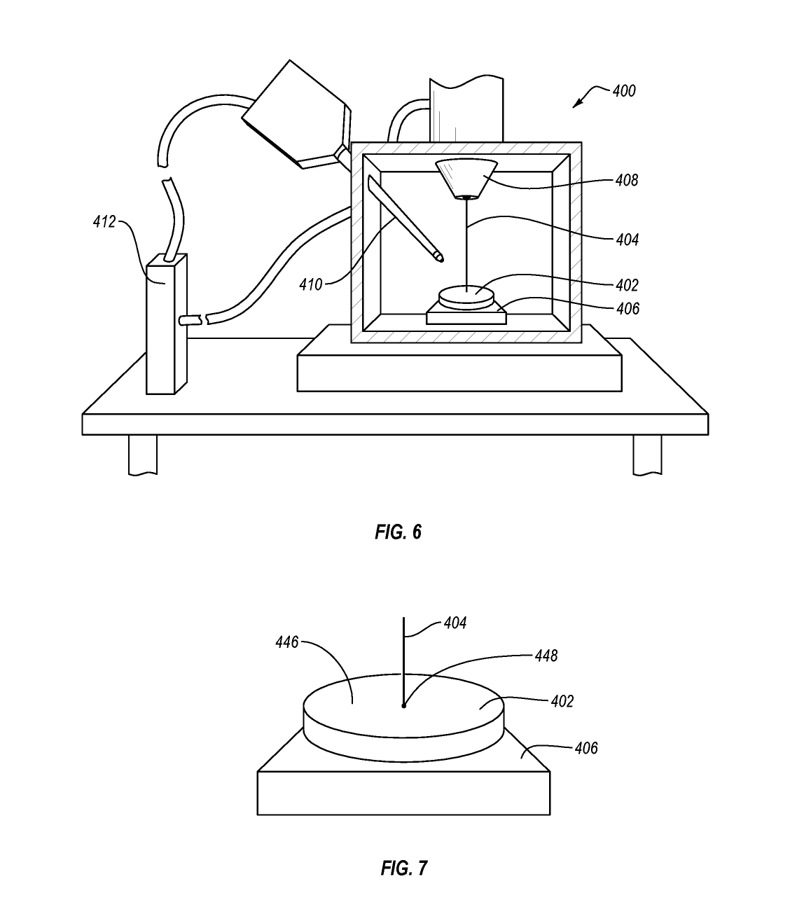

FIG. 6 illustrates the data collection system 400 with data communication between the SG 412 and the sampling location movement device 408, as well as the SG 412 and the signal detector 410. Upon the termination threshold or termination thresholds being met, the signal detector 410 may send a “complete” command to the SG 412 and the SG 412 may send a move command to the sampling location movement device 408. As shown in FIG. 7, the sampling location movement device may deflect or otherwise the move the beam 404 from a first sampling location 446 to a second sampling location 448 on the sample 402. In other embodiments, the sampling location movement device may move the stage 406 relative to the beam 404 to move the beam 404 from the first sampling location 446 to the second sampling location 448.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope. we claim:

1. A system for collecting information from a sample, the system including:
a scan generator, the scan generator being configured to communicate data through a first communication channel and a second communication channel; and
one or more signal detectors, the one or more signal detectors being in two-way data communication with the scan generator.

2. The system of claim 1, wherein the one or more signal detectors includes an X-ray spectrometer.

3. The system of claim 1, wherein the one or more signal detectors includes an electron backscatter diffraction detector.

4. The system of claim 1, wherein the one or more signal detectors includes an electron detector.

5. The system of claim 1, wherein the scan generator is configured to receive a location signal from the one or more signal detectors and send a stop command to the one or more signal detectors.

6. The system of claim 1, further comprising:
one or more sampling location movement devices, the one or more sampling location movement devices being in data communication with the scan generator through a first communication channel; and
an energy source.

7. A method for collecting information from a sample, the method including:
detecting a first location signal from a first sample location with a signal detector;
aggregating the first location signal into a total location signal;
comparing the total location signal to a termination threshold; and
if at least part of the total location sign meets or exceeds the termination threshold, stopping aggregating the first location signal and sending a complete command to a scan generator.

8. The method of claim 7, further comprising sending an acknowledgment signal from the scan generator to the signal detector upon receiving the complete command.

9. The method of claim 7, wherein comparing the total location signal to a termination threshold comprises comparing the total location signal to a first termination threshold and to a second termination threshold.

10. The method of claim 9, wherein if at least part of the total location signal meets or exceeds the first termination threshold or the second termination threshold, sending a complete command to the signal detector.

11. The method of claim 9, wherein if at least part of the total location sign meets or exceeds the first termination threshold and the second termination threshold, sending a complete command to the signal detector.

12. The method of claim 7, further comprising detecting a second location signal with a second signal detector simultaneously with the first location signal.

13. The method of claim 12, the second location signal is the same as the first location signal.

14. The method of claim 7, further comprising directing the energy source at a second sample location after sending the complete command to the signal detector.

15. The method of claim 7, further comprising sending the complete command if the termination threshold is not met or exceeded prior to a predetermined time out period.

16. The method of claim 7, further comprising storing the total location signal of the first sampling location in a data storage device.

17. A system for collecting information from a sample, the system comprising:
an energy source configured to provide an energy beam;
a scan generator having a first communication channel and a second communication channel;
one or more sampling location movement devices, the one or more sampling location movement devices being in data communication with the scan generator through the first communication channel, the one or more sampling location movement devices being configured to move the energy beam; and
one or more signal detectors, the one or more signal detectors being in data communication with the scan generator through the second communication channel, at least one of the one or more signal detectors being an energy dispersive X-ray spectrometer.

18. The system of claim 17, further comprising a data storage device in data communication with the one or more signal detectors.

19. The system of claim 17, wherein the energy source is an electron source.

20. The system of claim 17, further comprising a sample stage in data communication with the one or more sampling location movement devices.
